(19) United States
(12) Patent Application Publication
(10) Pub. No.: US 2019/0119812 A1
(43) Pub. Date: Apr. 25, 2019

(54) MANUFACTURE EQUIPMENT FOR LARGE-AREA PEROVSKITE FILM

(71) Applicant: CHANGZHOU UNIVERSITY, Jiangsu (CN)

(72) Inventors: Jianning DING, Jiangsu (CN); Shubo WANG, Jiangsu (CN); Ningyi YUAN, Jiangsu (CN); Xuguang JIA, Jiangsu (CN)

(21) Appl. No.: 16/230,205

(22) Filed: Dec. 21, 2018

Related U.S. Application Data
(63) Continuation of application No. PCT/CN2017/078529, filed on Mar. 29, 2017.

(30) Foreign Application Priority Data
Mar. 10, 2017 (CN) 201710139449.X

(51) Int. Cl. C23C 16/448; C23C 16/40; C23C 16/455; H01L 51/00; H01L 51/42; H01G 9/00; H01G 9/20

(52) U.S. Cl. CPC C23C 16/4481; C23C 16/409; C23C 16/455; H01G 9/2009; H01L 51/4253; H01G 9/0036; H01L 51/001

(57) ABSTRACT

A manufacture equipment for a large-area perovskite film, includes a vacuum chamber provided with a substrate heater therein for accommodating a substrate; a first evaporation case and a second evaporation case are disposed under the substrate heater in the vacuum chamber, the first evaporation case is embedded above the second evaporation case, a damper is disposed between the first evaporation case and the substrate heater; a first heater is disposed on the bottom of the first evaporation case, which is connected with a first carrier-gas pipe communicating with an external carrier-gas source; a second heater is disposed on the bottom of the second evaporation case, the second evaporation case is connected with a second carrier-gas pipe communicating with an external carrier-gas source. With the equipment, reaction species can be sprayed onto a substrate with carrier-gases and react to form perovskite film, which improves uniformity of the perovskite film.

### CROSS REFERENCE TO RELATED APPLICATIONS

This is a Continuation application of International Application Serial No. PCT/CN2017/078529, filed Mar. 29, 2017, which claims the benefit of Chinese Application No. 201710139449.X, filed Mar. 10, 2017, the disclosures of which are hereby incorporated by reference.

### BACKGROUND

The present invention relates to the technical field of solar cell, and in particular, to a manufacture equipment for large-area perovskite film.

Perovskite film solar cells develop quickly as next generation of high-efficiency film solar cell. In 2012, a first solid perovskite solar cell was disclosed with the efficiency of 9.7%. Within five years, the efficiency of small-area perovskite film solar cells has reached up to 21%. Currently, some industrial processes such as thermal spray-coating, thermal evaporation, CVD (Chemical Vapor Deposition) and the like have been developed to replace spin-coating process. However, those high-efficiency cells are all manufactured by spin-coating process and cannot be manufactured industrially in a large area.

### BRIEF SUMMARY

To overcome the defects of the prior art that the perovskite film cell cannot be manufactured industrially in a large area, the present invention provides a manufacture equipment for a large-area perovskite film.

The advantageous technical effects of the present invention includes: in comparison with the prior art, the manufacture equipment for a large-area perovskite film of the present invention can realize industrialized production; with a embedded spray nozzle, reaction species can be sprayed onto a substrate uniformly and controllably in a large area; with raw materials arranged outside a vacuum chamber, continuous production can be conducted without opening the vacuum chamber. Moreover, a gas-carrying process can improve uniformity of the large-area film in comparison with thermal evaporation, and can be controlled easily and has good repeatability in comparison with spin-coating and thermal spray coating and other processes.

To realize the object of the present invention, in one aspect, there is provided a manufacture equipment for a large-area perovskite film, comprising a vacuum chamber provided with a substrate heater therein for accommodating a substrate;

a first evaporation case and a second evaporation case are disposed under the substrate heater in the vacuum chamber, the first evaporation case has an open upper end, the second evaporation case is provided with a plurality of gas pipes vertically disposed on an upper end surface thereof; the first evaporation case is embedded above the second evaporation case, the upper ends of the respective gas pipes penetrate through a bottom surface of the first evaporation case and protrude inside the first evaporation case; a damper is disposed between the first evaporation case and the substrate heater to be opened and closed;

a first heater is disposed on the bottom of the first evaporation case for heating the bottom surface of the first evaporation case, the first evaporation case is connected with a first carrier-gas pipe communicating with an external carrier-gas source;

a second heater is disposed on a bottom of the second evaporation case for heating the bottom surface of the second evaporation case, the second evaporation case is connected with a second carrier-gas pipe communicating with an external carrier-gas source.

Further, a first gas preheater is provided on the first carrier-gas pipe, and a second gas preheater is provided on the second carrier-gas pipe.

Further, the gas preheater includes a metal heating body having a gas stream channel of Peano curve configuration therein.

Further, an orifice plate is provided above the opened upper end of the first evaporation case. The orifice plate is formed with a plurality of first and second gas pores respectively. The first gas pores are made for evaporated first solid evaporation source passing, and the second gas pores are made for evaporated second evaporation source passing; the first gas pore and the second gas pore are spaced apart and arranged alternately; the upper ends of the respective gas pipes of the second evaporation case are connected with the second gas pores.

Further, a vacuum pump set is provided under the vacuum chamber. The vacuum pump set is communicating with an internal cavity of the vacuum chamber and a butterfly valve is disposed at an inlet of the vacuum pump set; a film thickness gauge is disposed inside the vacuum chamber for measuring the thickness of the substrate.

In a second aspect, there is provided a manufacture equipment for a large-area perovskite film, comprising a vacuum chamber provided with a substrate heater therein for accommodating a substrate, a working face of the substrate heater facing downward;

a first evaporation case and a second evaporation case are disposed under the substrate heater in the vacuum chamber, the first evaporation case has an open upper end, the second evaporation case is provided with a plurality of gas pipes vertically disposed on an upper end surface thereof; the first evaporation case is embedded above the second evaporation case, the upper ends of the respective gas pipes penetrate through a bottom surface of the first evaporation case and protrude inside the first evaporation case; a damper is disposed between the first evaporation case and the substrate heater to be opened and closed;

the first evaporation case is connected with a first carrier-gas pipe communicating with an external carrier-gas source; a first raw material heating box is provided on the pipeline of the first carrier-gas pipe, and the first raw material heating box is connected with a first raw material feeding mechanism; a second raw material heating box is provided on the pipeline of the second carrier-gas pipe, and the second raw material heating box is connected with a second raw material feeding mechanism; the raw material feeding mechanisms serve for feeding raw materials to the raw material boxes.

Further, a first gas preheater is provided on the pipeline of the first carrier-gas pipe which lies upstream of the first raw material heating box, and a second gas preheater is provided on the pipeline of the second carrier-gas pipe which lies upstream of the second raw material heating box.

A heat-tracing heater is disposed inside the vacuum chamber, the heat-tracing heater is provided surrounding the outside of the first evaporation case and the second evaporation case.

Further, the gas preheater includes a metal heating body having a gas stream channel of Peano curve configuration therein.

Further, an orifice plate is provided above the opened upper end of the first evaporation case. The orifice plate is formed with a plurality of first and second gas pores respectively. The first gas pores are provided for evaporated first solid evaporation source passing, and the second gas pores are provided for evaporated second evaporation source passing. A first gas pore and a second gas pore are spaced apart and arranged alternately; the upper ends of the respective gas pipes of the second evaporation case are connected with the second gas pores.

Further, a vacuum pump set is provided under the vacuum chamber. The vacuum pump set is communicating with an internal cavity of the vacuum chamber and a butterfly valve is disposed at an inlet of the vacuum pump set. A film thickness gauge is disposed inside the vacuum chamber for measuring the thickness of the substrate.

As described above, the advantageous effects of the present invention lies in: with the manufacture equipment for a large-area perovskite film of the present invention, reaction species are sprayed onto the substrate with carrier-gases via the orifice plates so as to react and produce perovskite film, the uniformity of the perovskite film in large area deposition is greatly improved.

### BRIEF DESCRIPTION OF THE SEVERAL VIEWS OF THE DRAWINGS

Embodiments of the present invention will be described in the following with reference to accompanying drawings.

FIG. 1 is a schematic drawing of the manufacture equipment for a large-area perovskite film according to a first embodiment of the present invention; and

FIG. 2 is a schematic drawing of the manufacture equipment for a large-area perovskite film according to a second embodiment of the present invention.

### LIST OF REFERENCE NUMERALS

1: vacuum chamber 2: substrate heater 3: first evaporation case
31: first carrier-gas pipe 4: second evaporation case
41: second carrier-gas pipe 42: gas pipe 5: first heater
6: second heater 7: damper 8: film thickness gauge
9: orifice plate 91: first gas pore 92: second gas pore
11: first gas preheater 12: second gas preheater
13: first raw material heating box 14: second raw material heating box
15: first raw material feeding mechanism
16: second raw material feeding mechanism 17. heat-tracing heater

### DETAILED DESCRIPTION

The present invention will be further described with reference to specific embodiments. The drawings are all simplified schematic drawings illustrating the basic structure of the invention by way of example and showing only components relevant to the present invention.

### First Embodiment

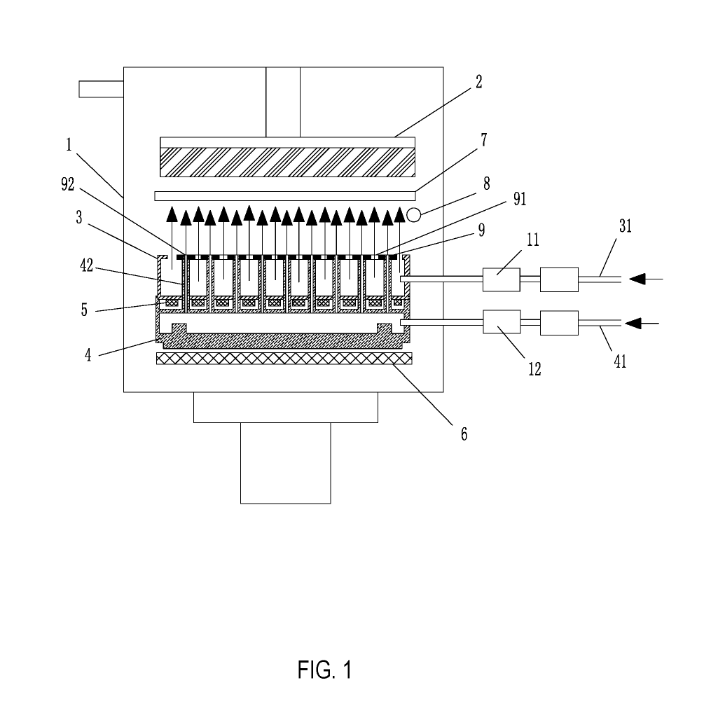

As shown in FIG. 1, a manufacture equipment for a large-area perovskite film comprises a vacuum chamber 1 which is a cavity within a vacuum box. A substrate heater 2 for heating a substrate is provided inside vacuum chamber 1. The substrate, such as glass, PET film, PI film, or stainless steel sheet, is clamped on the substrate heater and deposition is performed upwardly. Alternatively, a roller is provided under the substrate heater and the substrate is moved slowly on the roller so as to form a chain-type deposition equipment.

A first evaporation case 3 and a second evaporation case 4 are disposed under substrate heater 2 in vacuum chamber 1. First evaporation case 3 has an open upper end, and second evaporation case 4 is provided with a plurality of gas pipes 42 vertically disposed on an upper end surface thereof. First evaporation case 3 is embedded above second evaporation case 4, and upper ends of respective gas pipes 42 penetrate through a bottom surface of first evaporation case 3 and protrude in first evaporation case 3. A damper 7 which can be opened and closed is disposed between first evaporation case 3 and substrate heater 2. Damper 7 has a common connection structure. For example, damper 7 can be opened or closed by way of hinge connection.

A first heater 5 is disposed on the bottom of first evaporation case 3 for heating the bottom surface of first evaporation case 3. First evaporation case 3 is connected with a first carrier-gas pipe 31 communicating with an external carrier-gas source. A second heater 6 is disposed on a bottom of second evaporation case 4 for heating the bottom surface of second evaporation case 4, and second evaporation case 4 is connected with a second carrier-gas pipe 41 communicating with an external carrier-gas source.

A first gas preheater 11 is provided on the pipeline of first carrier-gas pipe 31, and a second gas preheater 12 is provided on the pipeline of second carrier-gas pipe 41.

The gas preheater includes a metal heating body having a gas stream channel of Peano curve configuration therein. With this structure, the gas in the carrier-gas pipe can be pre-heated sufficiently.

In order to mix the two evaporation gases uniformly, an orifice plate 9 is provided above the opened upper end of the first evaporation case 3. Orifice plate 9 is formed with a plurality of first gas pores 91 and a plurality of second gas pores 92 respectively. First gas pores 91 are provided for evaporated first solid evaporation source passing, and second gas pores 92 are provided for evaporated second evaporation source passing. First gas pore 91 and second gas pore 92 are spaced apart and arranged alternately. The upper ends of respective gas pipes 42 of second evaporation case 4 are connected with second gas pores 92.

A vacuum pump set is provided under vacuum chamber 1. The vacuum pump set is communicating with an internal cavity of vacuum chamber 1 and a butterfly valve is disposed at an inlet of the vacuum pump set. A film thickness gauge 8 is disposed inside vacuum chamber 1 for measuring the thickness of the substrate. Two gas-carrier pipes are each provided with a mass flow meter thereon.

In the present embodiment, the first solid evaporation source fed to first evaporation case 3 is methylamine iodine powder, and the second solid evaporation source fed to second evaporation case 4 is lead iodide and/or lead chloride. First evaporation case 3 is removably embedded above second evaporation case 4 to facilitate feeding evaporation source. First evaporation case 3 is made of stainless steel No. 316. The bottom of second evaporation case 4 is composed of a Quartz loading tank. The second heater 6 heats the Quartz loading tank.

When an operation is started, firstly, places the substrate on the heater, for example, the substrate can be fixed on the heater by way of clamping; lays lead iodide powder evenly on the Quartz loading tank of second evaporation case 4, and lays methyl amine iodine power evenly on the bottom of first evaporation case 3; then starts the vacuum pump set to pump until the vacuum degree is below 1E-5 Pa;

Secondly, turns on substrate heater 2 until the temperature reaches 80 degree centigrade and maintains 3-5 minutes; turns on the two gas preheaters to heat the carrier-gas pipes; argon gas is immitted at 100 sccm for the two carrier-gases; controls the butterfly valve to maintain a pressure of about 50 Pa within the vacuum chamber.

Thirdly, turns on second heater 6, controls the heating temperature to be 320 degree centigrade until the temperature is stable; then turns on a heater of first heater 5, controls the heating temperature to be 100 degree centigrade until the temperature is stable.

Fourthly, damper 7 is opened, then two kinds of evaporation source vapor is carried by the carrier-gas to be sprayed on the substrate and then reacts each other to generate a perovskite film. The film thickness is controlled by use of film thickness gauge 8 or controlled by time.

Finally, all the heaters are turned off, and the vacuum is released, and the manufactured film is picked out.

### Second Embodiment

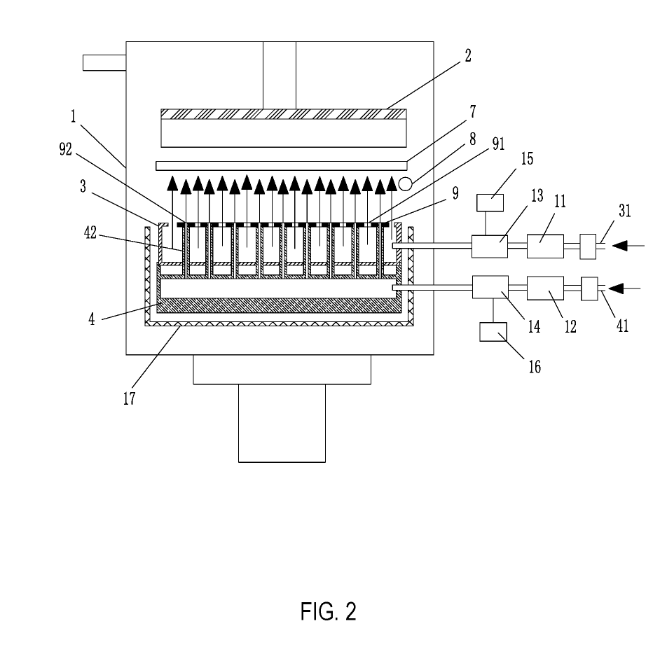

As shown in FIG. 2, a manufacture equipment for a large-area perovskite film comprises a vacuum chamber 1 which is a cavity within a vacuum box. A substrate heater 2 for heating a substrate is provided inside the vacuum chamber 1. The substrate is made of materials such as glass, PET film, PI film, stainless steel sheet and so on. When being mounted, the substrate can be clamped on the substrate heater and the deposition will be performed upwardly. Alternatively, a roller is provided under the substrate heater and the substrate is moved slowly on the roller to form a chain-type deposition equipment.

A first evaporation case 3 and a second evaporation case 4 are disposed under the substrate heater 2 in vacuum chamber 1. First evaporation case 3 has an open upper end, and second evaporation case 4 is provided with a plurality of gas pipes 42 vertically disposed on an upper end surface thereof. First evaporation case 3 is embedded above second evaporation case 4, and the upper ends of respective gas pipes 42 penetrate through a bottom surface of first evaporation case 3 and protrude in first evaporation case 3. A damper 7 which can be opened and closed is disposed between first evaporation case 3 and substrate heater 2. Damper 7 has a common connection structure. For example, damper 7 can be opened or closed by way of hinge connection.

First evaporation case 3 is connected with a first carrier-gas pipe 31 communicating with an external carrier-gas source. A first raw material heating box 13 is provided on pipeline of first carrier-gas pipe 31, and first raw material heating box 13 is connected with a first raw material feeding mechanism 15. A second raw material heating box 14 is provided on pipeline of second carrier-gas pipe 41, and second raw material heating box 14 is connected with a second raw material feeding mechanism 16. The raw material feeding mechanisms serve for feeding raw materials to the raw material boxes. First raw material feeding mechanism 15 adds the first solid evaporation source to first raw material box 13, and second raw material feeding mechanism 16 adds the second solid evaporation source to second raw material box 14.

A gas preheater includes a metal heating body having a gas stream channel of Peano curve configuration therein. When gas streams pass through this structure, the gas in the carrier-gas pipe can be preheated sufficiently.

A first gas preheater 11 is provided on first carrier-gas pipe 31 which lies upstream of first raw material heating box 13, and a second gas preheater 12 is provided on second carrier-gas pipe 41 which lies upstream of second raw material heating box 14. Further, a heat-tracing heater 17 is disposed inside vacuum chamber 1. Heat-tracing heater 17 is provided surrounding the outside of first evaporation case 3 and second evaporation case 4. Heat-tracing heater 17 serves to maintain the temperature inside the two evaporation cases.

In order to mix the two kinds of evaporation gas evenly, an orifice plate 9 is provided above the opened upper end of first evaporation case 3. Orifice plate 9 is formed with a plurality of first gas pores 91 and a plurality of second gas pores 92 respectively. First gas pores 91 are provided for evaporated first solid evaporation source passing, and second gas pores 92 are provided for evaporated second evaporation source passing. First gas pore 91 and second gas pore 92 are spaced apart and arranged alternately. The upper ends of respective gas pipes 42 of second evaporation case 4 are connected with second gas pores 92.

A vacuum pump set is provided under vacuum chamber 1. The vacuum pump set is communicating with an internal cavity of vacuum chamber 1 and a butterfly valve is disposed at an inlet of the vacuum pump set. A film thickness gauge 8 is disposed inside vacuum chamber 1 for measuring the thickness of the substrate.

When an operation is started, firstly, places the substrate on the heater, for example, the substrate can be fixed on the heater by way of clamping, then starts the vacuum pump set to pump until the vacuum degree is below 1E-5 Pa;

Secondly, turns on substrate heater 2 until the temperature reaches 80 degree centigrade and maintains 3-5 minutes, then turns on the two gas preheaters to heat the carrier-gas pipes, wherein the first preheater increases temperature up to 100 degree centigrade, and the second preheater increases temperature up to 320 degree centigrade, then argon gas is immitted at 100 sccm as the two carrier-gases, and controls the butterfly valve to maintain a pressure of about 50 Pa within the vacuum chamber.

Thirdly, turns on second raw material heating box 14, then a heating plate inside second raw material heating box 14 begins heating. Controls heating temperature to be 320 degree centigrade until the temperature is stable. Thereafter turns on first raw material heating box 13, then a heating plate inside first raw material heating box 13 will begin heating. Controls the heating temperature to be 100 degree centigrade until the temperature is stable. Second raw material feeding mechanism 16 feeds a suitable amount of lead iodid powder onto a heating plate inside second raw material heating box 14 and the amount of raw material to be fed is suitably adjusted as per the consumption of the raw material. First raw material feeding mechanism 15 feeds and lays a suitable amount of methyl amine iodine powder evenly onto a heating plate inside first raw material heating box 13 and the amount of raw material to be fed is suitably adjusted as per the consumption of the raw material.

Fourthly, the argon gas carries two the kinds of evaporation source vapor entering the respective evaporation cases. Heat-tracing heater 17 heats and controls the temperature inside the two evaporation cases. The working temperature of heat-tracing heater 17 is controlled at about 80 degree. The two kinds of carrier-gases are discharged via orifice plate 9 toward the lower side of damper 7 after heat-tracing.

Fifthly, when it is stable, damper 7 is opened, and the two kinds of evaporation source vapor are carried by argon gas to be sprayed onto the substrate and then reacts each other to generate perovskite film. The film thickness can be controlled by use of film thickness gauge 8 or controlled by time.

Finally, all the heaters are turned off, the vacuum is released, and the manufactured film is picked out.

In light of the preferred embodiments of the invention as described above, those skilled in the art can make various modifications and changes without departing the concept of the invention. The scope of the present invention should not be limited by the contents described in the specification, but be defined by the claims.

What is claimed is:

1. A manufacture equipment for a large-area perovskite film, wherein,
the equipment comprises a vacuum chamber provided with a substrate heater therein for accommodating a substrate,
a first evaporation case and a second evaporation case are disposed under the substrate heater in the vacuum chamber, the first evaporation case has an open upper end, the second evaporation case is provided with a plurality of gas pipes vertically disposed on an upper end surface thereof, the first evaporation case is embedded above the second evaporation case, the upper ends of the respective gas pipes penetrate through a bottom surface of the first evaporation case and protrude inside the first evaporation case, and a damper is disposed between the first evaporation case and the substrate heater to be opened and closed;
a first heater is disposed on the bottom of the first evaporation case for heating the bottom surface of the first evaporation case, the first evaporation case is connected with a first carrier-gas pipe communicating with an external carrier-gas source;
a second heater is disposed on a bottom of the second evaporation case for heating a bottom surface of the second evaporation case, the second evaporation case is connected with a second carrier-gas pipe communicating with an external carrier-gas source.

2. The manufacture equipment for a large-area perovskite film according to claim 1, wherein a first gas preheater is provided on the pipeline of the first carrier-gas pipe, and a second gas preheater is provided on the pipeline of the second carrier-gas pipe.

3. The manufacture equipment for a large-area perovskite film according to claim 2, wherein the gas preheaters each includes a metal heating body which has a gas stream channel of Peano curve configuration therein.

4. The manufacture equipment for a large-area perovskite film according to claim 1, wherein an orifice plate is provided above the opened upper end of the first evaporation case, the orifice plate is formed with a plurality of first gas pores and a plurality of second gas pores respectively, the first gas pores are provided for evaporated first solid evaporation source passing, the second gas pores are provided for evaporated second evaporation source passing, each the first gas pore and the second gas pore are spaced apart and arranged alternately; the upper ends of the respective gas pipes of the second evaporation case are connected with the second gas pores.

5. The manufacture equipment for a large-area perovskite film according to claim 1, wherein
a vacuum pump set is provided under the vacuum chamber, the vacuum pump set is communicating with an internal cavity of the vacuum chamber and a butterfly valve is disposed at an inlet of the vacuum pump set; and
a film thickness gauge is disposed inside the vacuum chamber for measuring the thickness of the substrate.

6. A manufacture equipment for a large-area perovskite film, wherein
the equipment comprises a vacuum chamber provided with a substrate heater therein for accommodating a substrate;
a first evaporation case and a second evaporation case are disposed under the substrate heater in the vacuum chamber, the first evaporation case has an open upper end, the second evaporation case is provided with a plurality of gas pipes vertically disposed on an upper end surface thereof, the first evaporation case is embedded above the second evaporation case, the upper ends of the respective gas pipes penetrate through a bottom surface of the first evaporation case and protrude inside the first evaporation case, and a damper is disposed between the first evaporation case and the substrate heater to be opened and closed,
the first evaporation case is connected with a first carrier-gas pipe communicating with an external carrier-gas source;
a first raw material heating box is provided on the first carrier-gas pipe, and the first raw material heating box is connected with a first raw material feeding mechanism;
a second raw material heating box is provided on the second carrier-gas pipe, and the second raw material heating box is connected with a second raw material feeding mechanism;
the raw material feeding mechanisms serve for feeding raw materials to the raw material boxes.

7. The manufacture equipment for a large-area perovskite film according to claim 6, wherein
a first gas preheater is provided on the pipeline of the first carrier-gas pipe which lies upstream of the first raw material heating box, and a second gas preheater is provided on the pipeline of the second carrier-gas pipe which lies upstream of the second raw material heating box; and
a heat-tracing heater is disposed inside the vacuum chamber, the heat-tracing heater is provided surrounding the outside of the first evaporation case and the second evaporation case.

8. The manufacture equipment for a large-area perovskite film according to claim 7, wherein the gas preheaters each includes a metal heating body which has a gas stream channel of Peano curve configuration therein.

9. The manufacture equipment for a large-area perovskite film according to claim 6, wherein an orifice plate is provided above the opened upper end of the first evaporation case, the orifice plate is formed with a plurality of first gas pores and a plurality of second gas pores respectively, the first gas pores are provided for evaporated first solid evaporation source passing, the second gas pores are provided for evaporated second evaporation source passing, each the first gas pore and the second gas pore are spaced apart and arranged alternately; the upper ends of the respective gas pipes of the second evaporation case are connected with the second gas pores.

10. The manufacture equipment for a large-area perovskite film according to claim 6, wherein
a vacuum pump set is provided under the vacuum chamber, the vacuum pump set is communicating with an internal cavity of the vacuum chamber and a butterfly valve is disposed at an inlet of the vacuum pump set; and
a film thickness gauge is disposed inside the vacuum chamber for measuring the thickness of the substrate.
